(19) United States
(12) Patent Application Publication
(10) Pub. No.: US 2024/0313504 A1
(43) Pub. Date: Sep. 19, 2024

(54) LASER LIGHT SOURCE FOR AIMING DEVICE AND A LASER LIGHT SOURCE ADAPTER CIRCUIT BOARD FOR AIMING DEVICE

(71) Applicants: Haoqian Liu, Lake Oswego, OR (US); Xiaobo Liu, ZhongShan City (CN); Zhilong Liu, ZhongShan City (CN)

(72) Inventors: Haoqian Liu, Lake Oswego, OR (US); Xiaobo Liu, ZhongShan City (CN); Zhilong Liu, ZhongShan City (CN)

(21) Appl. No.: 18/597,378

(22) Filed: Mar. 6, 2024

(30) Foreign Application Priority Data
Mar. 16, 2023 (CN) 202320519947.8

(51) Int. Cl. H01S 5/042; H01S 5/42

(52) U.S. Cl. CPC H01S 5/04256; H01S 5/423

(57) ABSTRACT

This utility model discloses a laser light source for aiming device, comprising a laser chip. The top layer of the laser chip is equipped with a light source set, which comprises at least two laser light sources. The laser chip is equipped with an electrode laminate connected to an electrode of the laser light source at the bottom layer and the laser chip is further equipped with an electrode terminal set at the top layer. The electrode terminal set comprises several electrode terminals, the electrode terminal corresponds to the laser light source one to one, and the other electrode of each laser light source is connected to the corresponding electrode terminal. This utility model aims to overcome the shortcomings of exiting technology and provide a laser light source for aiming device in a wider range of scenarios.

### CROSS-REFERENCE TO RELATED APPLICATIONS

This application claims benefit under 35 U.S.C. § 119 of Chinese Non-Provisional Application having Ser. No. 202320519947.8 filed Mar. 16, 2023, and issued as Chinese Patent No. 2023031700643560, which is hereby incorporated by reference herein in its entirety.

### FIELD OF TECHNOLOGY

This utility model specifically relates to a laser light source for aiming device, and further relates to a laser light source adapter circuit board for aiming device.

### BACKGROUND

The aiming device is an observation device that can be used to position objects on the same straight line, assist objects in aligning with specific targets, and can be applied to firearms, crossbows, telescopes and other equipment. However, sighting devices that apply the optical principle are not within the scope of this definition. General aiming devices include light sources. The light emitted by the light source is reflected and refracted through the optical lens to form a luminous sight bead on one lens. However, the sight bead used in different equipment has different shapes and patterns of the aiming device. The traditional aiming device can only form a single sight bead graph, so both the range of applications and function are very limited. In addition, traditional aiming devices mostly use LED as the light source, but this type of light source has poor light penetration and high power consumption.

This utility model is created based on the shortcomings aforesaid.

### Content of Utility Model

This utility model aims to overcome the shortcomings of existing technology and provide a laser light source suitable for a wider range of scenarios for aiming devices.

The utility model is achieved through the following technical solutions:

A laser light source for aiming device, comprising a laser chip, wherein the top layer of the laser chip is equipped with a light source set, which comprises at least two laser light sources. The laser chip is equipped with an electrode laminate connected to an electrode of the laser light source at the bottom layer and the laser chip is further equipped with an electrode terminal set at the top layer; the electrode terminal set comprises several electrode terminals, the electrode terminal corresponds to the laser light source one to one, and the other electrode of each laser light source is connected to the corresponding electrode terminal.

The laser light source for aiming device aforesaid, wherein the light source set comprises three laser light sources: a red dot light source, a segmented arc light source and a pattern identification light source. The electrode terminal set comprises three electrode terminals: a first electrode terminal, a second electrode terminal, and a third electrode terminal. The first electrode terminal, the second electrode terminal and the third electrode terminal correspond to the red dot light source, segmented arc light source, and pattern identification light source one to one respectively. The other electrodes of the red dot light source, segmented arc light source, and pattern identification light source are respectively connected to the first electrical terminal, the second electrical terminal, and the third electrical terminal.

The laser light source aforesaid, wherein the negative poles of the red dot light source, segmented arc light source, and pattern identification light source are connected to the electrode laminate respectively, and the positive poles of the red dot light source, segmented arc light source and pattern identification light source are respectively connected to the first electrical pole, the second electrical pole, and the third electrical pole.

The laser light source aforesaid wherein the red dot light source is in the shape of dot.

The laser light source aforesaid, wherein the segmented arc light source comprises of several arc strips that are concentric and have the same radius with the red dot light source.

The laser light source aforesaid, wherein the segmented arc light source comprises four arc strips uniformly distributed along the circumference, and the pattern identification light source comprises a pattern block set between adjacent arc strips.

A laser light source adapter circuit board for aiming device, comprising of a circuit board, wherein the circuit board is equipped with a laser chip aforesaid, and the circuit board is provided with a first bonding pad at the front for mounting the laser chip and connecting it to the electrode laminate. The circuit board is also equipped with three second bonding pads at the front corresponding to the first electrode terminal, the second electrode terminal and the third electrode terminal respectively. The circuit board aforesaid is equipped with four third bonding pads on the back corresponding to a first bonding pad and three second bonding pads respectively.

The laser light source adapter circuit board for aiming device aforesaid, wherein the circuit board is made of gold-plated FR4 substrate or gold-plated ceramic board substrate.

Compared with the existing technology, the utility model has the following advantages:

The laser chip of this utility model can independently control different laser light sources. When in use, different sight beads or combinations of sight beads can be displayed in the viewfinder of the electric aiming device, in order to adapt to various different scenarios. A single product can match multiple different devices at the same time.

### SUMMARY

In one aspect, a laser device is disclosed. The laser device includes a laser chip including a top layer and a bottom layer. A set of laser light sources is coupled to the laser chip. The set of laser light sources includes a first laser light source configured to project a first type of light pattern and a second laser light source configured to project a second type of light pattern and a third laser light source configured to project a third type of light pattern. In the bottom layer, the laser light source includes a first positive electrode or a first negative electrode. The second laser light source includes a second positive electrode or a second negative electrode. The third laser light source includes a third positive electrode or a third negative electrode. A set of electrode terminals in the top layer include a first electrode terminal and a second electrode terminal and a third electrode terminal. The first electrode terminal is connected to either the first positive electrode or to the first negative electrode. The second electrode terminal is connected to either the second positive electrode or to the second negative electrode. The third electrode terminal is connected to either the third positive electrode or to the third negative electrode.

In another aspect, a laser light source adapter device is disclosed. The device includes a circuit board. A laser chip is coupled to the circuit board. A first laser light source on the laser chip is configured to project a first type of light pattern by operation of a first signal from the circuit board. A second laser light source on the laser chip is configured to project a second type of light pattern by operation of a second signal from the circuit board. A third laser light source on the laser chip is configured to project a third type of light pattern by operation of a third signal from the circuit board. The first laser light source includes a first positive electrode and a first negative electrode. The second laser light source includes a second positive electrode and a second negative electrode. The third laser light source includes a third positive electrode and a third negative electrode. A set of electrode terminals is coupled to the laser chip, including a first electrode terminal and a second electrode terminal and a third electrode terminal. The first electrode terminal is connected to either the first positive electrode or to the first negative electrode. The second electrode terminal is connected to either the second positive electrode or to the second negative electrode. The third electrode terminal is connected to either the third positive electrode or to the third negative electrode.

### DESCRIPTION OF DRAWINGS

The detailed description of some embodiments of the invention is made below with reference to the accompanying figures, wherein like numerals represent corresponding parts of the figures.

FIG. 1 is a three dimensional view of the laser chip of the present utility model;

FIG. 2 is a schematic diagram of the laser chip of this utility model;

FIG. 3 is a front view of the circuit board of the present utility model;

FIG. 4 is a back view of the circuit board of the present utility model.

FIG. 5A is an illustration of a laser output in the shape of a dot, consistent with embodiments disclosed herein.

FIG. 5B is an illustration of a laser output in the shape of a set of cross-hairs, consistent with embodiments disclosed herein.

FIG. 5C is an illustration of a laser output in the shape of arc segments concentric about a common center, consistent with embodiments disclosed herein.

FIG. 5D is an illustration of a laser output in the shape of cross-hairs, according to another embodiment.

FIG. 5E is an illustration of a laser output in the shape of cross-hairs, according to another embodiment.

FIG. 5F is an illustration of a laser output in the shape of cross-hairs, according to another embodiment.

### DETAILED DESCRIPTION OF CERTAIN EMBODIMENTS

### Specific Embodiment

The following is a further description of the utility model based on the accompanying drawings:

The orientations described in the detailed description of the utility model, such as “up”, “down”, “left”, “right”, “front”, “back”, etc., are based on the orientation as shown in the drawings, intended to facilitate the description of the relationships between various components rather than indicating the unique or absolute positional relationships between components, and only intended to achieve one embodiment of the utility model rather than a limitation on its embodiment.

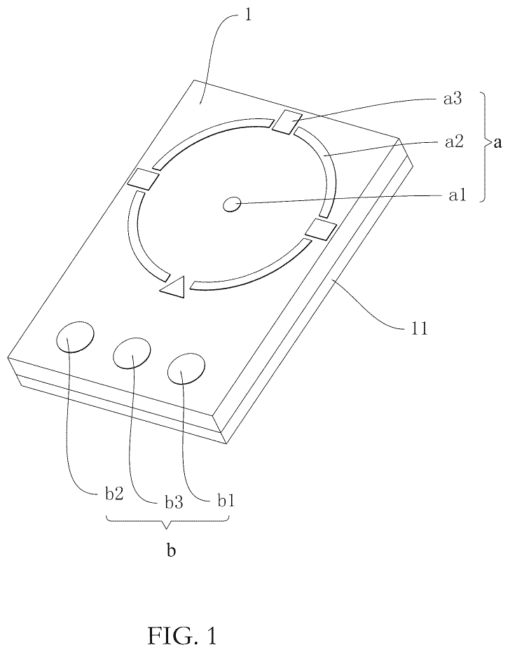

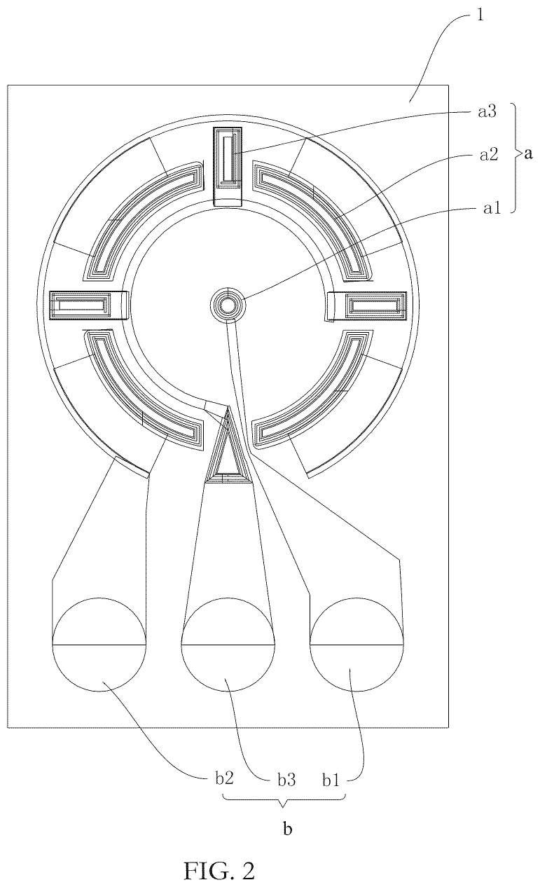

As shown in FIGS. 1 and 2, a laser light source for aiming device comprises a laser chip 1. The top layer of the laser chip is equipped with a light source set a, which comprises three laser light sources: red dot light source a1, a segmented arc light source a2 and a pattern identification light source a3. The laser chip 1 is equipped with an electrode laminate 11 connected to an electrode of the laser light source at the bottom layer and the laser chip 1 is further equipped with an electrode terminal set b at the top layer; the electrode terminal set b comprises three electrode terminals: a first electrode terminal b1, a second electrode terminal b2, and a third electrode terminal b3. The first electrode terminal b1, the second electrode terminal b2 and the third electrode terminal b3 correspond to the red dot light source a1, segmented arc light source a2, and pattern identification light source a3 one to one respectively. The positive electrodes of the red dot light source a1, segmented arc light source a2, and pattern identification light source a3 are respectively connected to the first electrical terminal b1, the second electrical terminal b2, and the third electrical terminal b3. Of course, it is also possible to switch between the positive and negative electrodes. Through the, above structure, the red dot light source a1, segmented arc light source a2, and pattern identification light source a3 can be separately controlled to switch on and off, displaying different sight beads or different combinations of sight beads in the viewfinder of the aiming device and adapting to various different scenarios accordingly. A single product can match with multiple different devices simultaneously.

Of course, the composition of light source set a does not necessarily comprise three light sources. It only needs to comprise two or more laser light sources, and the electrode terminal set b corresponds to the light source set a one to one.

As shown in FIG. 1, as an embodiment, the red dot light source a1 is in the shape of a dot and the segmented arc light source a2 comprises several arc strips that are concentric and have the same radius with the red dot light source a1. The segmented arc light source a2 comprises four arc strips uniformly distributed along the circumference, and the pattern identification light source a3 comprises a pattern block set between adjacent arc strips. Of course, various laser sources can also be in other shapes, such as human shaped target, circular target and triangular target.

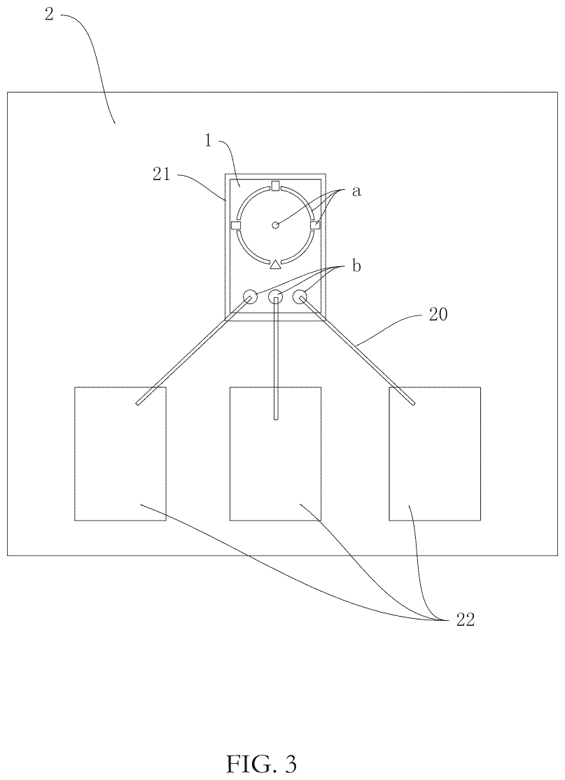

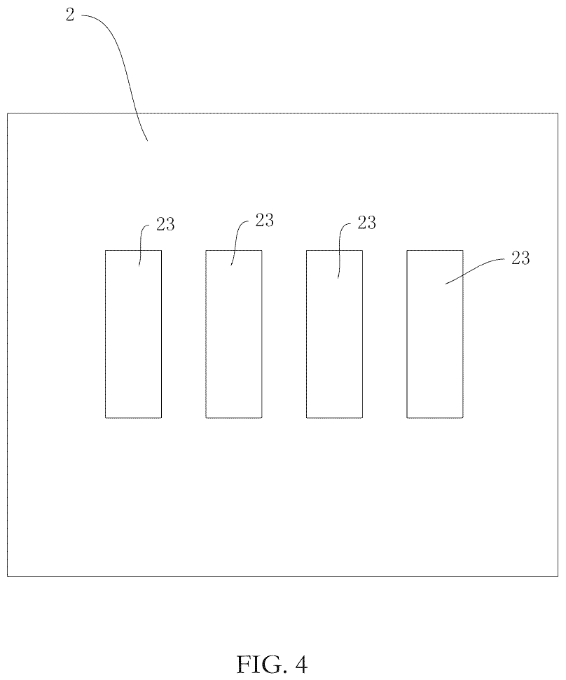

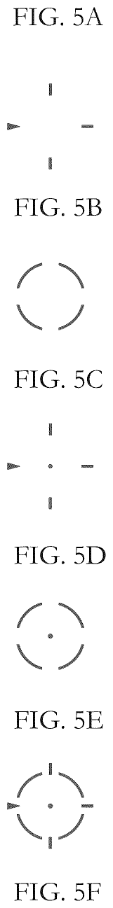

As shown in FIGS. 3 and 4, a laser light source adapter circuit board for aiming device comprises a circuit board 2, wherein the circuit board 2 is equipped with a laser chip 1, and the circuit board 2 is provided with a first bonding pad 21 at the front for mounting the laser chip 1 and connecting it to the electrode laminate 11. The circuit board 2 is also equipped with three second bonding pads 22 at the front corresponding to the first electrode terminal b1, the second electrode terminal b2 and the third electrode terminal b3 respectively. The second bonding pad is used for connecting the first electrode terminal b1, the second electrode terminal b2 and the third electrode terminal b3 through the gold wire 20. The circuit board 2 is equipped with four third bonding pads 23 on the back corresponding to a first bonding pad 21 and three second bonding pads 22 respectively. The third bonding pad 23 is used for connecting the external circuit so as to control the switching-in and switching-off of various laser light source circuits.

Preferably, the circuit board 2 is made of gold-plated FR4 substrate or gold-plated ceramic board substrate.

The above is only an embodiment of the present utility model, and the specific structure and characteristics commonly known in the plan are not described in detail herein. It should be pointed out that, based on the structure of the present utility model, technicians in this field may make several deformations and improvements, which should also be considered as the scope of the protection of the present utility model and will not affect the effectiveness of the implementation of the present utility model and the practicality of the patent. The scope of protection required by this application should be based on the content of its claims, and the specific embodiment methods, etc. in the detailed description can be used to interpret the content of the which should also be considered as the scope of claims.

1. A laser device, comprising:
a laser chip including a top layer and a bottom layer;
a set of laser light sources coupled to the laser chip, wherein the set of laser light sources includes:
a first laser light source configured to project a first type of light pattern; and
a second laser light source configured to project a second type of light pattern; and
a third laser light source configured to project a third type of light pattern;
a first positive electrode or a first negative electrode of the first laser light source, in the bottom layer;
a second positive electrode or a second negative electrode of the second laser light source, in the bottom layer;
a third positive electrode or a third negative electrode of the third laser light source, in the bottom layer;
a set of electrode terminals in the top layer, including a first electrode terminal and a second electrode terminal and a third electrode terminal, wherein:
the first electrode terminal is connected to either the first positive electrode or to the first negative electrode; and
the second electrode terminal is connected to either the second positive electrode or to the second negative electrode.
the third electrode terminal is connected to either the third positive electrode or to the third negative electrode.

2. The laser device of claim 1, wherein the first laser light source is controllable independent of the second laser light source and the third laser light source.

3. The laser device of claim 1, further comprising an electrode laminate in the bottom layer, connected to the first positive electrode or the first negative electrode, the second positive electrode or the second negative electrode, the third positive electrode or the third negative electrode.

4. The laser device of claim 1, wherein the first type of light pattern and the second type of light pattern and the third type of light pattern are selected from two or more of a dot-shaped output, a segmented arc, and a set of cross-hairs.

5. The laser device of claim 4, wherein the laser chip is configured to generate the set of cross-hairs in a variety of cross-hair patterns.

6. The laser device of claim 4, wherein the laser chip is configured to generate the segmented arc as comprising a plurality of concentric arc strips.

7. The laser device of claim 6, wherein the laser chip is configured to generate a pattern block positioned between adjacent arc strips.

8. The laser device of claim 1, wherein the laser chip is a vertical-cavity surface-emitting laser (VCSEL).

9. A laser light source adapter device, comprising:
a circuit board;
a laser chip coupled to the circuit board;
a first laser light source on the laser chip, configured to project a first type of light pattern by operation of a first signal from the circuit board;
a second laser light source on the laser chip, configured to project a second type of light pattern by operation of a second signal from the circuit board;
a third laser light source on the laser chip, configured to project a third type of light pattern by operation of a third signal from the circuit board;
a first positive electrode and a first negative electrode of the first laser light source;
a second positive electrode and a second negative electrode of the second laser light source;
a third positive electrode and a third negative electrode of the third laser light source;
a set of electrode terminals coupled to the laser chip, including a first electrode terminal and a second electrode terminal and a third electrode terminal, wherein:
the first electrode terminal is connected to either the first positive electrode or to the first negative electrode; and
the second electrode terminal is connected to either the second positive electrode or to the second negative electrode.
the third electrode terminal is connected to either the third positive electrode or to the third negative electrode.

10. The laser light source adapter device of claim 9, wherein the circuit board is configured to first laser light source is controllable independent of the second laser light source and the third laser light source.

11. The laser light source adapter device of claim 9, wherein the first type of light pattern and the second type of light pattern and the third type of light pattern are selected from two or more of a dot-shaped output, a segmented arc, and a set of cross-hairs.

12. The laser light source adapter device of claim 11, wherein the laser chip is configured to generate the set of cross-hairs in a variety of cross-hair patterns.

13. The laser light source adapter device of claim 11, wherein the laser chip is configured to generate the segmented arc as comprising a plurality of concentric arc strips.

14. The laser light source adapter device of claim 13, wherein the laser chip is configured to generate a pattern block positioned between adjacent arc strips.

15. The laser light source adapter device of claim 9, wherein the laser chip is a vertical-cavity surface-emitting laser (VCSEL).
